(19) United States
(12) Patent Application Publication
(10) Pub. No.: US 2015/0129134 A1
(43) Pub. Date: May 14, 2015

(54) PLACEMENT TABLE AND PLASMA PROCESSING APPARATUS

(71) Applicant: TOKYO ELECTRON LIMITED, Tokyo (JP)

(72) Inventors: Naoki MATSUMOTO, Miyagi (JP); Daisuke HAYASHI, Miyagi (JP)

(73) Assignee: TOKYO ELECTRON LIMITED, Tokyo (JP)

(21) Appl. No.: 14/539,397

(22) Filed: Nov. 12, 2014

(30) Foreign Application Priority Data
Nov. 13, 2013 (JP) 2013-235194

(51) Int. Cl. H01L 21/683; H01L 21/67

(52) U.S. Cl. CPC H01L 21/6831; H01L 21/67098
USPC 156/345.52; 361/234; 118/723 R

(57) ABSTRACT

A placement table includes: a base; an electrostatic chuck disposed on the base and including a placement surface on which a workpiece is placed; a plurality of heat generating members disposed at a side opposite to the placement surface of the electrostatic chuck; a power supply configured to generate a current for causing each of the plurality of heat generating members to generate heat; a plurality of electric wires installed to extend in a direction crossing the placement surface from the plurality of heat generating members, respectively, and configured to connect the power supply with the heat generating members, respectively; and a filter mounted on each of the plurality of electric wires to remove a high frequency component having a frequency higher than that of the current generated by the power supply.

### CROSS-REFERENCE TO RELATED APPLICATIONS

This application is based on and claims priority from Japanese Patent Application No. 2013-235194, filed on Nov. 13, 2013, with the Japan Patent Office, the disclosure of which is incorporated herein in its entirety by reference.

### TECHNICAL FIELD

The present disclosure relates to a placement table and a plasma processing apparatus.

### BACKGROUND

In the related art, in a plasma processing apparatus, a workpiece is placed on a placement table disposed inside of a processing container. The placement table includes, for example, a base, and an electrostatic chuck mounted on the base and including a placement surface on which the workpiece is placed.

However, in the plasma processing apparatus, it is requested to maintain temperature uniformity of the electrostatic chuck in order to perform a uniform plasma processing on an entire processing target surface of the workpiece. Regarding this, there is a technology for heating an electrostatic chuck in which a plurality of electrostatic chucks is disposed at a side opposite to the placement surface, and a plurality of electric wires is provided to extend parallel to the placement surface of the electrostatic chuck from the plurality of heat generating members, respectively, and an electric current is caused to flow between the heat generating members and a power supply through the electric wires, thereby heating the electrostatic chuck. See, for example, U.S. Patent Application Publication No. 2011/0092072.

### SUMMARY

According to an aspect of the present disclosure, a placement table includes a base; an electrostatic chuck disposed on the base and including a placement surface on which a workpiece is placed; a plurality of heat generating members disposed at a side opposite to the placement surface of the electrostatic chuck; a power supply configured to generate a current for causing each of the plurality of heat generating members to generate heat; a plurality of electric wires installed to extend in a direction crossing the placement surface from the plurality of heat generating members, respectively, and configured to connect the power supply with the heat generating members, respectively; and a filter mounted on each of the plurality of electric wires to remove a high frequency component having a frequency higher than that of the current generated by the power supply.

The foregoing summary is illustrative only and is not intended to be in any way limiting. In addition to the illustrative aspects, embodiments, and features described above, further aspects, exemplary embodiments, and features will become apparent by reference to the drawings and the following detailed description.

### BRIEF DESCRIPTION OF THE DRAWINGS

FIG. 1 is a cross-sectional view illustrating an entire configuration of a plasma processing apparatus according to a first exemplary embodiment.

FIG. 2 is a cross-sectional view illustrating a configuration of a placement table in the first exemplary embodiment.

FIG. 3 is a plan view illustrating a positional relationship among an electrostatic chuck, a focus ring, and heat generating members included in the placement table in the first exemplary embodiment.

FIG. 4 is a cross-sectional view illustrating a configuration of a placement table in a second exemplary embodiment.

FIG. 5 is a plan view illustrating a positional relationship among an electrostatic chuck, a focus ring, and heat generating members in a third exemplary embodiment.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made without departing from the spirit or scope of the subject matter presented here.

The above-described prior art has a problem in that resistance to radio frequency (RF) noise is damaged.

For example, when the electric wires, which are installed to extend parallel to the placement surface of the electrostatic chuck from the plurality of heat generating members, respectively, are electrically coupled to plasma, RF noise may be applied to the electric wires from the coupled plasma. In such a case, the power supply connected to the heat generating members through the electric wires may be damaged by the RF noise applied to the electric wires. For this reason, resistance to RF noise may be damaged.

According to an aspect of a placement table disclosed hereinbelow, resistance to RF noise may be improved.

Hereinafter, exemplary embodiments of a placement table and a plasma processing apparatus will be described in detail with reference to the accompanying drawings. The present disclosure is not limited by the exemplary embodiments. The exemplary embodiments may be properly combined with each other without causing inconsistency to processing contents in each of the exemplary embodiments.

### First Exemplary Embodiment

In an example, a placement table according to the first exemplary embodiment includes: a base, an electrostatic chuck disposed on the base and including a placement surface on which a workpiece is placed; a plurality of heat generating members disposed at a side opposite to the placement surface of the electrostatic chuck; a power supply configured to generate a current for causing each of the plurality of heat generating members to generate heat; a plurality of electric wires installed to extend in a direction crossing the placement surface from the plurality of heat generating members, respectively and configured to connect the power supply with the heat generating members, respectively; and a filter mounted on the electric wire to remove a high frequency component having a frequency higher than that of the current generated by the power supply.

In an example, the placement table according to the first exemplary embodiment further includes a bonding layer configured to bond the base and the electrostatic chuck with each other. The plurality of heat generating members is embedded in the bonding layer to be disposed at the side opposite to the placement surface of the electrostatic chuck.

In an example, in the placement table according to the first exemplary embodiment, the electrostatic chuck includes a plurality of recesses on a bottom surface which is a surface opposite to the placement surface of the electrostatic chuck, and the plurality of heat generating members is accommodated in the plurality of recesses, respectively.

In an example, in the placement table according to the first exemplary embodiment, the electrostatic chuck and each of the plurality of heat generating members are formed integrally with each other.

In an example, in the placement table according to the first exemplary embodiment, each of the plurality of heat generating members is formed in at least one of a polygonal shape, a circular shape, and a fan shape.

In an example, in the placement table according to the first exemplary embodiment, each of the plurality of heat generating members is formed in a polygonal shape, and a diagonal length of each of the plurality of heat generating members is in a range of 1 cm to 12 cm.

In an example, in the placement table according to the first exemplary embodiment, each of the plurality of heat generating members is formed in a circular shape, and a diameter of each of the plurality of heat generating members is in a range of 1 cm to 5 cm.

In an example, in the placement table according to the first exemplary embodiment, the plurality of heat generating members is disposed radially at the side opposite to the placement surface of the electrostatic chuck.

In an example, in the placement table according to the first exemplary embodiment, the electrostatic chuck is an insulator enclosing an electrode, each of the plurality of heat generating members is an insulator enclosing a heater, and the insulators include at least one of Y₂O₃, Al₂O₃, SiC, YF₃, and AlN.

In an example, the placement table according to the first exemplary embodiment further includes a focus ring provided on the base to surround the electrostatic chuck. Some of the plurality of heat generating members is positioned at a position corresponding to the focus ring at the side opposite to the placement surface of the electrostatic chuck.

In an example, the placement table according to the first exemplary embodiment further includes: a high frequency power supply connected to the base and configured to supply a high frequency power having a frequency higher than a frequency of the current to the base. The filter has a transmission band which blocks the frequency of the high frequency power and transmits the frequency of the current.

In an exemplary embodiment, in the placement table according to the first exemplary embodiment, the filter is an inductor formed by winding an electric wire or an LC circuit formed as a filter element.

In an example, a plasma processing apparatus according to the first exemplary embodiment includes a placement table. The placement table includes: a base; an electrostatic chuck disposed on the base and including a placement surface on which a workpiece is placed; a plurality of heat generating members disposed at a side opposite to the placement surface of the electrostatic chuck; a power supply configured to generate a current for causing each of the plurality of heat generating members to generate heat; a plurality of electric wires installed to extend in a direction crossing the placement surface from the plurality of heat generating members, respectively, and configured to connect the power supply with the heat generating members, respectively; and a filter mounted on each of the plurality of electric wires to remove a high frequency component having a frequency higher than that of the current generated by the power supply.

(Configuration of Plasma Processing Apparatus of First Exemplary Embodiment)

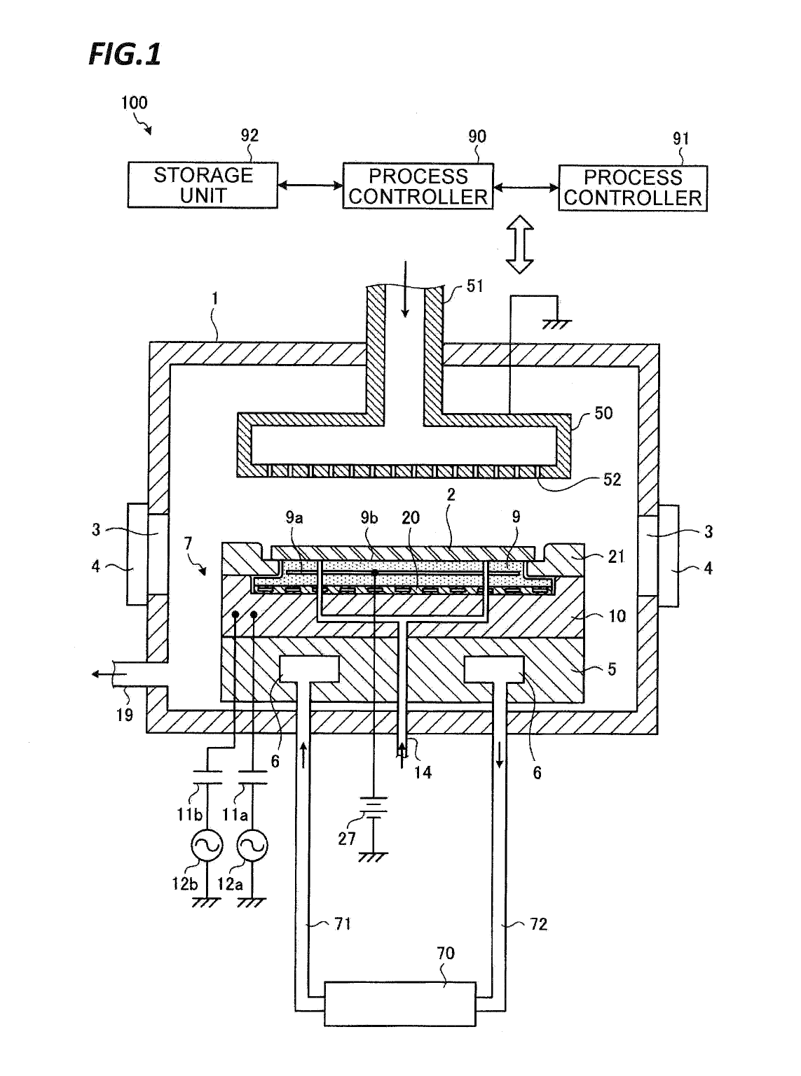

FIG. 1 is a cross-sectional view illustrating an entire configuration of a plasma processing apparatus according to the first exemplary embodiment. As illustrated in FIG. 1, the plasma processing apparatus 100 includes a chamber 1. The chamber 1 includes an outer wall which is formed of a conductive aluminum. In the example illustrated in FIG. 1, the chamber 1 includes an opening 3, through which a semiconductor wafer 2 as a workpiece is carried into/out of the chamber 1, and a gate valve 10 configured to be opened/closed via a sealing member for hermetic sealing. The sealing member is, for example, an O-ring.

Although not illustrated in FIG. 1, a load-lock chamber is provided to be continued to the chamber 1 through the gate valve 4. The load-lock chamber is provided with a conveyance apparatus. The conveyance apparatus carries the semiconductor wafer 2 into/out of the chamber 1.

In addition, the chamber 1 includes a discharge port 19 on a lower portion of a side wall thereof in which the discharge port 19 is opened to reduce the pressure inside of the chamber 1. The discharge port 19 is connected to an evacuating device (not illustrated) through an opening/closing valve such as, for example, a butterfly valve. The evacuating device refers to, for example, a rotary pump or a turbo molecular pump.

In addition, as illustrated in FIG. 1, the plasma processing apparatus 100 includes a support table 5 on a central portion of the bottom of the chamber 1. In addition, the plasma processing apparatus 100 includes a placement table 7 disposed inside of the chamber 1 and configured to place the semiconductor wafer 2 thereon. The detailed configuration of the placement table 7 will be described later.

The placement table 7 is supported by the support table 5. The placement table 7 and the support table 5 are provided with a supply piping 14 so as to uniformly supply a heat transfer medium to the rear surface of the semiconductor wafer 2. The heat transfer medium refers to, for example, an inert gas such as He gas. Without being limited thereto, however, any other gas may be used.

The support table 5 is a conductive member such as, for example, aluminum and is formed in a cylindrical shape. The support table 5 includes a coolant jacket 6 configured to fix a cooling medium therein. The coolant jacket 6 includes a flow path 71 configured to introduce the cooling medium into the coolant jacket 6, and a flow path 72 configured to discharge the cooling medium, in which the flow paths 71 and 72 are hermetically installed through the bottom of the chamber 1.

Hereinafter, descriptions will be made on a case where the coolant jacket 6 is installed inside of the support table 5 as an example, but the present disclosure is not limited thereto. For example, the coolant jacket 6 may be installed inside of the placement table 7. The coolant jacket 6 controls the temperature of the placement table 7 or the support table 5 by circulating the cooling medium by a chiller 70 as described below.

In addition, the plasma processing apparatus 100 includes an upper electrode 50 above the placement table 7 and in the upper portion of the chamber 1. The upper electrode 50 is electrically grounded. A processing gas is supplied to the upper electrode 50 through a gas supply pipe 51 from a gas supply mechanism (not illustrated), and is discharged toward the wafer 2 from a plurality of radial small holes 52 perforated through the bottom wall of the upper electrode 50. Here, when the high frequency power supply 12a is turned ON, plasma is generated between the upper electrode 50 and the semiconductor wafer 2 by the discharged processing gas. The processing gas refers to, for example, CHF₃ or CF₄.

In addition, the plasma processing apparatus 100 includes a chiller 70 configured to circulate the cooling medium in the coolant jacket 6. Specifically, the chiller 70 discharges the cooling medium from the flow path 71 to the coolant jacket 6, and receives the cooling medium coming out from the coolant jacket 6, from the flow path 72.

In addition, each component of the plasma processing apparatus 100 is connected to and controlled by a process controller 90 which is provided with a central processing unit (CPU). A user interface 91 is connected to the process controller 90, in which the user interface 91 includes, for example, a keyboard on which a process manager performs, for example, an input operation of a command for managing the plasma processing apparatus 100 or a display which visualizes and displays an operating situation of the plasma processing apparatus 100.

In addition, a storage unit 92 is connected to the process controller 90, in which the storage unit 92 is stored with control programs for implementing various processings performed in the plasma processing apparatus 100 under the control of the process controller, or recipes recorded with, for example, processing requirement data.

A desired processing in the plasma processing apparatus 100 may be performed under the control of the process controller 90 by calling for any recipe by, for example, an instruction from the user interface 91 from the storage unit 92 and causing the recipe to be executed by the process controller 90. The recipes may be used in a state where they are stored in a computer-readable storage medium such as, for example, a CD-ROM, a hard disc, a flexible disc, or a flash memory, or by causing the recipes to be frequently transmitted from any other device through, for example, a dedicated line. The process controller 90 may also be referred to as a “control unit”. The functions of the process controller 90 may be implemented either by being operated using software or by being operated using hardware.

(Configuration of Placement Table)

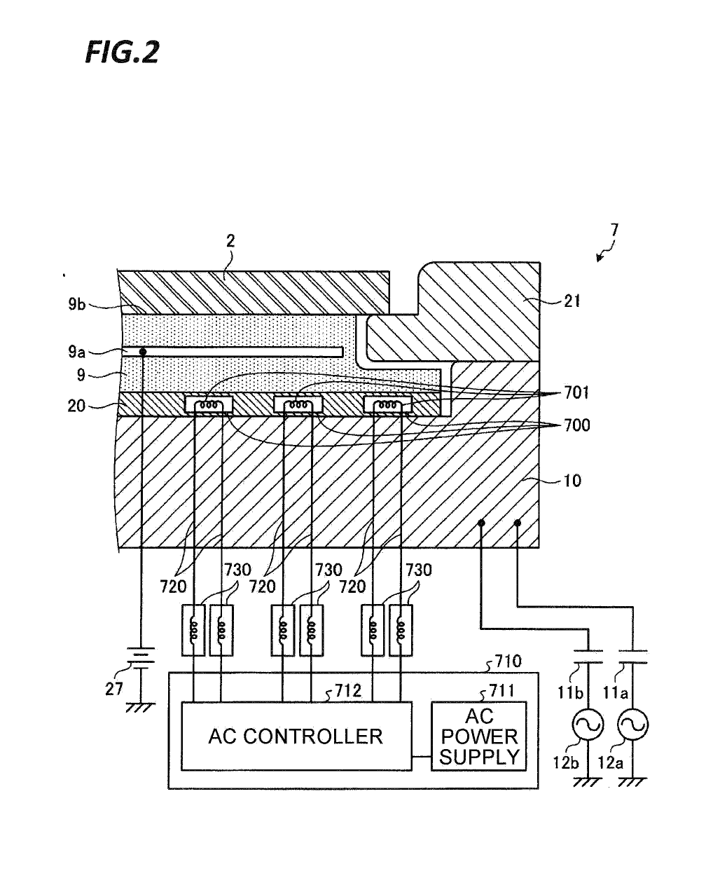

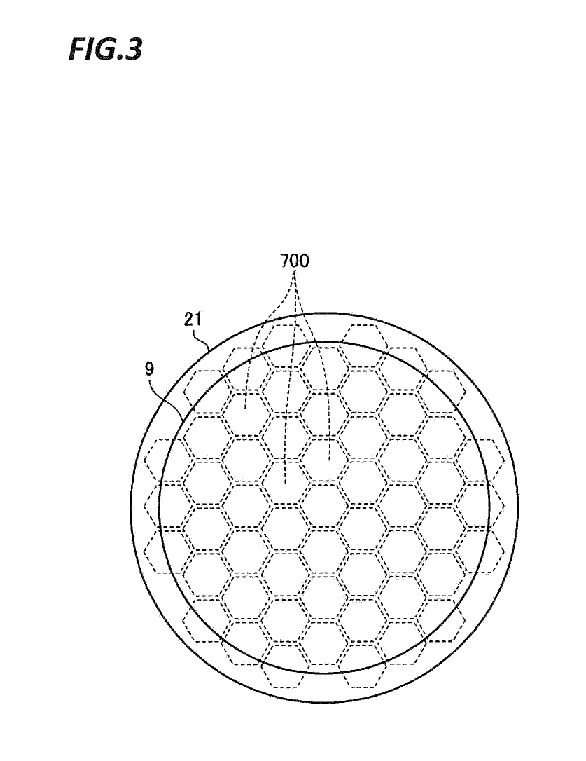

Here, descriptions will be made on the detailed configuration of the placement table 7 illustrated in FIG. 1. FIG. 2 is a cross-sectional view illustrating the configuration of the placement table in the first exemplary embodiment. FIG. 3 is a plan view illustrating a positional relationship among an electrostatic chuck, a focus ring, and heat generating members included in the placement table in the first exemplary embodiment.

As illustrated in FIG. 2, the placement table 7 includes a base 10 installed on the support table 5, an electrostatic chuck 9 installed on the base 10, and a focus ring 21 installed on the base 10 to surround the electrostatic chuck 9.

The base 10 is formed of, for example, aluminum. The base 10 is connected with the high frequency power supply 12a through a blocking condenser 11a. The high frequency power supply 12a supplies a high frequency power having a predetermined frequency (e.g., 100 MHz) to the base 10 as a high frequency power for plasma generation. The high frequency power for plasma generation, which is supplied to the base 10 from the high frequency power supply 12a, has a frequency higher than the current generated by an AC power supply 711 to be described later.

The base 10 is also connected with a high frequency power supply 12b through a blocking condenser 11b. The high frequency power supply 12b supplies a high frequency power having a predetermined frequency (e.g., 13 MHz) lower than that of the high frequency power supply 12a, to the base 10, as a high frequency power for ion drawing-in (bias). The high frequency bias power for bias, which is supplied to the base 10 from the high frequency power supply 12b, has a frequency higher than the current generated by the AC power supply 711 to be described later.

The base 10 and the electrostatic chuck 9 are bonded to each other by a bonding layer 20. The bonding layer 20 serves to buffer stresses of the electrostatic chuck 9 and the base 10 and bonds the base 10 and the electrostatic chuck 9 to each other.

The electrostatic chuck 9 is an insulator enclosing an electrode 9a. The electrostatic chuck 9 includes a placement surface 9b on which a semiconductor wafer 2 is placed. An insulator forming the electrostatic chuck 9 contains at least one of, for example, Y₂O₃, Al₂O₃, SiC, YF₃, and AlN. The electrode 9a is connected to a direct current (DC) power supply 27. The electrostatic chuck 9 attracts and holds the semiconductor wafer 2 on the placement surface 9b by a Coulomb force generated by a DC voltage applied to the electrode 9a from the DC power supply 27.

As illustrated in FIG. 2, the placement table 7 further includes a plurality of heat generating members 700 disposed at a side opposite to the placement surface 9b of the electrostatic chuck 9, and a power supply 710 configured to generate a current for causing each of the plurality of heat generating member 700 to generate heat. In addition, the placement table 7 further includes a plurality of electric wires 720 which is configured to connect the power supply 710 with the plurality of heat generating members 700, respectively, and a filter 730 mounted on each of the electric wires 720.

The plurality of heat generating members 700 is embedded in the bonding layer 20 to be disposed at the side opposite to the placement surface 9b of the electrostatic chuck 9. In the example illustrated in FIGS. 2 and 3, the plurality of heat generating members 700 is embedded in the bonding layer 20 to be disposed at the side opposite to the placement surface 9b of the electrostatic chuck 9 in a grid shape. Each of the plurality of heat generating members 700 is an insulator enclosing a heater 701. The insulator forming each of the plurality of heat generating members 700 includes at least one of, for example, Y₂O₃, Al₂O₃, SiC, YF₃, and AlN. The insulator forming each of the plurality of heat generating members 700 may be either different from or the same as the insulator forming the electrostatic chuck 9. The heater 701 may be formed by, for example, a metal wire to generate heat by Joule's heat when a current flows therein. When the heater 701 generates heat, the electrostatic chuck 9 is heated from the bottom surface opposite to the placement surface 9b of the electrostatic chuck 9.

Some of the heat generating members 700 are disposed along a position corresponding to the focus ring 21 at the side opposite to the placement surface 9b of the electrostatic chuck 9. In the example of FIGS. 2 and 3, the heat generating members 700 disposed at the outermost among the plurality of heat generating members 700 are disposed along the position corresponding to the focus ring 21 at the side opposite to the placement surface 9b of the electrostatic chuck 9. As a result, the focus ring 21 is heated by the heat generating members 700 disposed along the position corresponding to the focus ring 21 at the side opposite to the placement surface 9b of the electrostatic chuck 9.

Each of the plurality of heat generating members 700 is formed in at least one shape selected from a polygonal shape, a circular shape, and a fan shape in a plan view. In the example of FIG. 3, each of the plurality of heat generating members 700 is formed in a hexagonal shape in the plan view. When each of the plurality of heat generating members 700 is formed in the polygonal shape, the diagonal length of each of the plurality of heat generating members 700 may be in a range of 1 cm to 12 cm. When each of the plurality of heat generating members 700 is formed in a circular shape in the plan view, the diameter of each of the plurality of heat generating members 700 may be in a range of 1 cm to 5 cm.

The power supply 710 includes an AC power supply 711 and an AC controller 712. The AC power supply 711 outputs a current for causing each of the plurality of heat generating members 700 (hereinafter, merely referred to as a “current”) to the AC controller 712. The AC controller 712 distributes the current input from the AC power supply 711 to the electric wires 720 in a predetermined ratio so as to separately control the heat generation from the plurality of heat generating members 700.

The electric wires 720 are installed to extend along a direction crossing the placement surface 9b of the electrostatic chuck 9 from the plurality of heat generating members 700, respectively. For example, the electric wires 720 are installed to extend in a direction orthogonal to the placement surface 9b of the electrostatic chuck 9 from the plurality of heat generating members 700, respectively. The ends of the entire wires 720, each of which extends from one of the plurality of heat generating members 700, are connected to the AC controller 712 of the power supply 710. The currents distributed by the AC controller 712 are supplied to the plurality of heat generating members 700 through the electric wires 720, respectively, and the electrostatic chuck 9 is heated by each of the plurality of heat generating members 700.

Here, a relationship between the electric wires 720 and the electrostatic chuck 9 will be additionally described. As described above, the electric wires 720 are installed to extend along the direction crossing the placement surface 9b of the electrostatic chuck 9 from the plurality of heat generating members 700, respectively. In other words, the electric wires 720 are installed to extend in the direction, where a projected area of the electric wires 720 on the placement surface 9b of the electrostatic chuck 9 is minimized, from the plurality of heat generating members 700, respectively. When the projected area of the electric wires 720 on the placement surface 9b of the electrostatic chuck 9 is minimized, electric coupling between the plasma generated between the upper electrode 50 and the semiconductor wafer 2 on the placement surface 9b and the electric wires 720 hardly occurs. As a result, RF noise applied to the electric wires 720 from the plasma is suppressed.

Each of the filters 730 removes a high frequency component having a frequency higher than that of the current generated by the power supply 710. Specifically, the filters 730 have a transmission band which blocks the high frequency power for plasma generation, which is supplied from the high frequency power supply 12a, and the high frequency power for bias, which is supplied from the high frequency power supply 12b, and transmits the frequency of the current generated by the power supply 710. Here, RF noise applied to the electric wires 720 from the high frequency power for plasma generation and the high frequency power for bias and RF noise applied to the electric wires 720 from the plasma are high frequency components having a frequency higher than that of the current generated by the power supply 710. For this reason, either the RF noise applied to the electric wires 720 from the high frequency power for plasma generation and the high frequency power for bias or the RF noise applied to the electric wires 720 from the plasma is blocked by the filters 730. As a result, the RF noise applied to the electric wires 720 hardly infiltrates into the power supply 710 through the electric wires 720, and thus the damage of the power supply 710 by the RF noise may be avoided.

In addition, each of the filters 730 is an inductor formed by winding each electric wire 720 or an LC circuit formed as a filter element. The number of turns of winding the electric wire 720 is properly set such that a high frequency component having a frequency higher than that of the current generated by the power supply 710 may be removed by the filter 730. In addition, the filter may be a commercially available LC circuit which is formed as a filter element.

### Effect of First Exemplary Embodiment

As described above, in the plasma processing apparatus 100 according to the first exemplary embodiment, the placement table 7 includes a base 10, an electrostatic chuck 9 placed on the base 10 and including a placement surface 9b on which a workpiece is placed, a plurality of heat generating member 700 disposed at the side opposite to the placement surface 9b of the electrostatic chuck 9, a power supply 710 configured to generate a current for causing each of the plurality of heat generating members 700 to generate heat, and a plurality of electric wires 720 installed to extend along a direction crossing the placement surface 9b from the plurality of heat generating members 700, respectively, and a plurality of filters 730 mounted on the electric wires mounted on the plurality of electric wires 720, respectively, and configured to remove a frequency component having a frequency higher than that of the current generated by the power supply 710. As a result, resistance to RF noise may be enhanced.

Here, a heating method is considered in which the plurality of heat generating members is disposed at the side opposite to the placement surface of the electrostatic chuck, and the plurality of electric wires is installed to extend parallel to the placement surface of the electrostatic chuck from the plurality of heat generating members, respectively, and the heat generating members and the power supply are electrically connected with each other through the electric wires, respectively. In the placement table using this heating method, the area of some of the electric wires opposite to the plasma generated between the upper electrode and the placement surface of the workpiece on the electrostatic chuck, in other words, the projected area of the electric wires on the placement surface of the electrostatic chuck increases. For this reason, electric coupling of the plasma and the electric wires is facilitated. When the electric wires are electrically coupled to the plasma, RF noise may be applied to the electric wires from the coupled plasma. In such a case, the power supply connected to the heat generating members through the electric wires may be damaged by the RF noise applied to the electric wires.

As compared to the placement table using the heating method, according to the placement table 7 in the first exemplary embodiment, the plurality of electric wires 720 extends along a direction crossing the placement surface 9b from the plurality of heat generating members 700. For this reason, the projected area of the wires 720 with on the placement surface 9b of the electrostatic chuck 9 may be minimized, and the electric coupling between the plasma generated between the upper electrode 50 and the semiconductor wafer 2 on the placement surface 9b is hardly caused. Accordingly, the RF noise applied to the electric wires 720 from the plasma is suppressed. In addition, according to the placement table 7 of the first exemplary embodiment, the filters 730 configured to remove a high frequency component having a frequency higher than that of the current generated by the power supply 710 are mounted on the electric wires 720, respectively. For this reason, even if RF noise is applied to the electric wires 720 from the plasma, the RF noise applied to the electric wires 720 from the plasma is blocked by the filters 730. As a result, the RF noise applied to the electric wires 720 hardly infiltrates to the power supply 710 through the electric wires 720 so that the damage of the power supply 710 by the RF noise is avoided. That is, resistance to RF noise may be improved.

According to the placement table 7 in the first exemplary embodiment, the plurality of heat generating members 700 is embedded in the bonding layer 20 that bonds the base 10 and the electrostatic chuck 9 to each other to be disposed on the side opposite to the placement surface 9b of the electrostatic chuck 9. For this reason, peeling-off of the base 10, the electrostatic chuck 9, and the plurality of heat generating members 700 may be prevented and displacement of the electric wires 720, which extend respectively from the plurality of heat generating members 700, may be avoided. As a result, resistance to RF noise may be further improved.

According to the placement table 7 in the first exemplary embodiment, each of the plurality of heat generating members 700 is formed in at least one of a polygonal shape, a circular shape, and a fan shape. For this reason, the plurality of heat generating members 700 may be properly arranged, and displacement or break of the electric wires 720, which extend from the plurality of heat generating members 700, respectively, may be avoided. As a result, resistance to RF noise may be further improved.

According to the placement table 7 in the first exemplary embodiment, when each of the plurality of heat generating members 700 is formed in a polygonal shape, the diagonal length of each of the plurality of heat generating members 700 is in a range of 1 cm to 12 cm. For this reason, the temperature uniformness of each of the plurality of heat generating members 700 satisfies a predetermined tolerance. As a result, resistance to RF noise may be improved while enhancing accuracy in temperature control using the plurality of heat generating members 700.

According to the placement table 7 in the first exemplary embodiment, when each of the plurality of heat generating members 700 is formed in a circular shape, the diameter of each of the plurality of heat generating members 700 is in the range of 1 cm to 5 cm. For this reason, the temperature uniformness of each of the plurality of heat generating members 700 satisfies a predetermined tolerance. As a result, resistance to RF noise may be improved while enhancing accuracy in temperature control using the plurality of heat generating members 700.

According to the placement table 7 in the first exemplary embodiment, the electrostatic chuck 9 is an insulator enclosing an electrode 9a, each of the plurality of heat generating members 700 is an insulator enclosing a heater 701, and the insulators include at least one of Y₂O₃, Al₂O₃, SiC, YF₃, and MN. For this reason, the temperature uniformness of each of the plurality of heat generating members 700 satisfies a predetermined tolerance. As a result, resistance to RF noise may be improved while enhancing accuracy in temperature control using the plurality of heat generating members 700.

According to the placement table 7 in the first exemplary embodiment, the placement table 7 further includes a focus ring 21 installed on the base 10 to surround the electrostatic chuck 9, and some of the heat generating members 700 are disposed along the position corresponding to the focus ring 21 at the opposite side to the placement surface 9b of the electrostatic chuck 9. For this reason, the focus ring 21 may be heated by the heat generating members 700 disposed along the position corresponding to the focus ring 21. As a result, resistance to RF noise may be improved while enhancing uniformness in temperature distribution on the focus ring 21.

According to the placement table 7 in the first exemplary embodiment, the placement table 7 further includes high frequency power supplies 12a and 12b connected to the base 10 and configured to supply a high frequency power having a frequency higher than the current of the power supply 710 to the base 10, and the filters 730 have a transmission band which blocks the frequency of the high frequency power and transmits the frequency of the current of the power supply 710. For this reason, either RF noise applied to the electric wires 720 from the high frequency power for plasma generation and the high frequency power for bias or RF noise applied to the electric wires 720 from the plasma may be blocked by the filters 730. As a result, damage of the power supply 710 by RF noise is reliably avoided.

According to the placement table 7 in the first exemplary embodiment, each of the filters 730 is an inductor formed by winding each electric wire 720 or an LC circuit formed as a filter element. As a result, the filters 730 configured to remove a frequency component having a frequency higher than that of the current generated by the power supply 710 may be simply mounted on the electric wires 720. Further, each of the filters 730 may be a commercially available LC circuit formed as a filter element.

### Other Exemplary Embodiments

Although the placement table and the plasma processing apparatus according to the first exemplary embodiment have been described above, the present disclosure is not limited thereto. Hereinafter, other exemplary embodiments will be described.

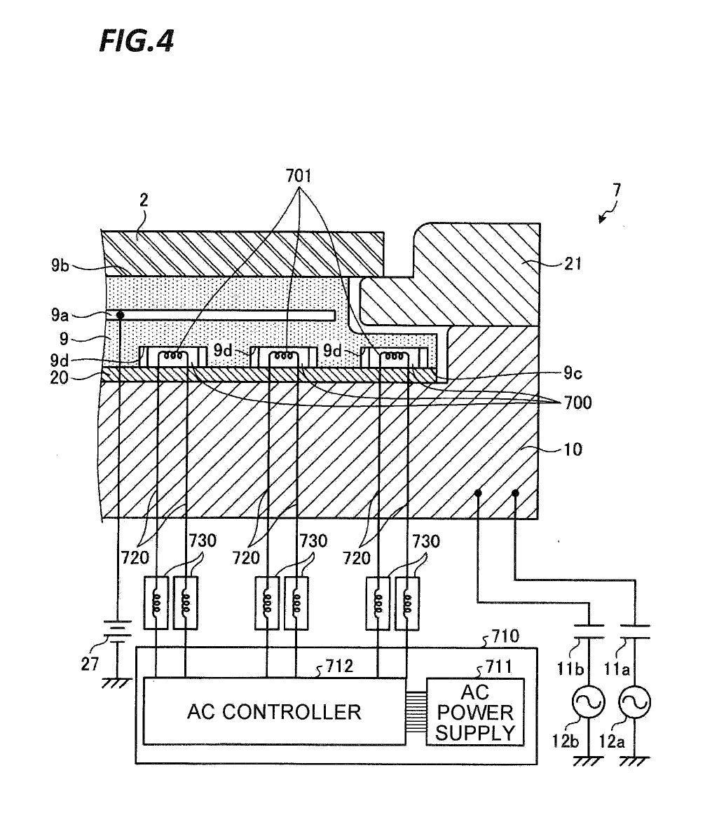

For example, although in the placement table 7 of the first exemplary embodiment, the plurality of heat generating members 700 is embedded in the bonding layer 20 to be disposed at the opposite side to the placement surface 9b of the electrostatic chuck 9, the present disclosure is not limited thereto. Hereinafter, a placement table according to a second exemplary embodiment will be described. FIG. 4 is a cross-sectional view illustrating a configuration of the placement table in the second exemplary embodiment.

As illustrated in FIG. 4, in the placement table 7 in the second exemplary embodiment, the electrostatic chuck 9 includes a plurality of recesses 9d formed on a bottom surface 9 which is the opposite side to the placement surface 9b, and the plurality of heat generating members 700 are accommodated in the plurality of recesses 9d, respectively.

According to the placement table 7 in the second exemplary embodiment, adhesion between the electrostatic chuck 9 and the plurality of heat generating members 700 is improved, and displacement and break of the electric wires 720 which extend respectively from the plurality of heat generating members 700 may be avoided. As a result, uniformness in temperature distribution on the electrostatic chuck 9 may be improved and resistance to RF noise may be further enhanced.

In addition, although the example illustrated in FIG. 4 illustrates a case in which the electrostatic chuck 9 and each of the plurality of heat generating members 700 is formed as separate components, the present disclosure is not limited thereto. The electrostatic chuck 9 and each of the plurality of heat generating members 700 may be integrally formed. In such a case, the insulator forming each of the plurality of heat generating members 700 and the insulator forming the electrostatic chuck 9 are formed of the same insulator.

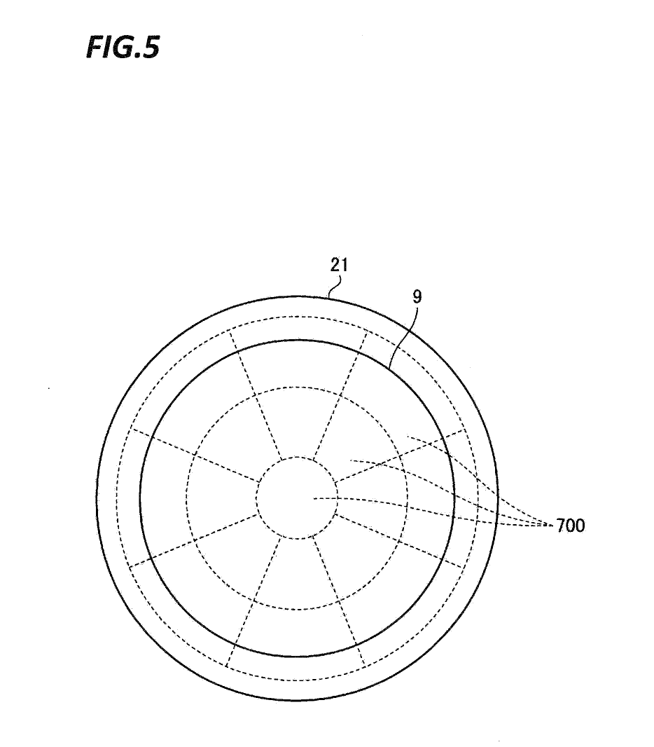

In the placement table 7 in the first exemplary embodiment, although the plurality of heat generating members 700 is arranged in a grid form on the opposite side to the placement surface 9b of the electrostatic chuck 9, the present disclosure is not limited thereto. Hereinafter, a placement table 7 in a third exemplary embodiment will be described. FIG. 5 is a plan view illustrating a positional relationship of an electrostatic chuck, a focus ring, and heat generating members included in a placement table in the third exemplary embodiment.

As illustrated in FIG. 5, in the placement table 7 in the third exemplary embodiment, the plurality of heat generating members 700 is radially arranged at the opposite side to the placement surface 9b of the electrostatic chuck 9. In the example illustrated in FIG. 5, among the plurality of heat generating members 700, the heat generating members 700 having a fan shape are radially arranged along a radial direction with the heat generating member 700 having a circular shape and arranged in the central portion of the electrostatic chuck 9 as a center. In addition, in the example illustrated in FIG. 5, the heat generating members disposed at the outermost side among the plurality of heat generating members 700 are arranged at a position corresponding to the focus ring 21 at the opposite side to the placement surface 9b of the electrostatic chuck 9.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A placement table comprising:
a base;
an electrostatic chuck disposed on the base and including a placement surface on which a workpiece is placed;
a plurality of heat generating members disposed at a side opposite to the placement surface of the electrostatic chuck;
a power supply configured to generate a current for causing each of the plurality of heat generating members to generate heat;
a plurality of electric wires installed to extend in a direction crossing the placement surface from the plurality of heat generating members, respectively, and configured to connect the power supply with the heat generating members, respectively; and
a filter mounted on each of the plurality of electric wires to remove a high frequency component having a frequency higher than that of the current generated by the power supply.

2. The placement table of claim 1, further comprising:
a bonding layer configured to bond the base and the electrostatic chuck with each other,
wherein the plurality of heat generating members is embedded in the bonding layer to be disposed at the side opposite to the placement surface of the electrostatic chuck.

3. The placement table of claim 1, wherein the electrostatic chuck includes a plurality of recesses on a bottom surface which is a surface opposite to the placement surface of the electrostatic chuck, and
the plurality of heat generating members is accommodated in the plurality of recesses, respectively.

4. The placement table of claim 3, wherein the electrostatic chuck and each of the plurality of heat generating members are formed integrally with each other.

5. The placement table of claim 1, wherein each of the plurality of heat generating members is formed in at least one of a polygonal shape, a circular shape, and a fan shape.

6. The placement table of claim 1, wherein each of the plurality of heat generating members is formed in a polygonal shape, and
a diagonal length of each of the plurality of heat generating members is in a range of 1 cm to 12 cm.

7. The placement table of claim 1, wherein each of the plurality of heat generating members is formed in a circular shape, and
a diameter of each of the plurality of heat generating members is in a range of 1 cm to 5 cm.

8. The placement table of claim 1, wherein the plurality of heat generating members is disposed radially at the side opposite to the placement surface of the electrostatic chuck.

9. The placement table of claim 1, wherein the electrostatic chuck is an insulator enclosing an electrode,
each of the plurality of heat generating members is an insulator enclosing a heater, and
the insulators include at least one of Y₂O₃, Al₂O₃, SiC, YF₃, and AlN.

10. The placement table of claim 1, further comprising:
a focus ring provided on the base to surround the electrostatic chuck,
wherein some of the plurality of heat generating members are positioned at a position corresponding to the focus ring at the side opposite to the placement surface of the electrostatic chuck.

11. The placement table of claim 1, further comprising:
a high frequency power supply connected to the base and configured to supply a high frequency power having a frequency higher than a frequency of the current to the base,
wherein the filter has a transmission band which blocks the frequency of the high frequency power and transmits the frequency of the current.

12. The placement table of claim 1, wherein the filter is an inductor formed by winding an electric wire or an LC circuit formed as a filter element.

13. A plasma processing apparatus comprising a placement table, the placement table including:
a base;
an electrostatic chuck disposed on the base and including a placement surface on which a workpiece is placed;
a plurality of heat generating members disposed at a side opposite to the placement surface of the electrostatic chuck;
a power supply configured to generate a current for causing each of the plurality of heat generating members to generate heat;
a plurality of electric wires installed to extend in a direction crossing the placement surface from the plurality of heat generating members, respectively, and configured to connect the power supply with the heat generating members, respectively; and
a filter mounted on each of the plurality of electric wires to remove a high frequency component having a frequency higher than that of the current generated by the power supply.
